(19) United States
(12) Patent Application Publication
(10) Pub. No.: US 2016/0172096 A1
(43) Pub. Date: Jun. 16, 2016

(54) ELECTRONIC COMPONENT AND BOARD HAVING THE SAME

(71) Applicant: SAMSUNG ELECTRO-MECHANICS CO., LTD., Suwon-Si (KR)

(72) Inventors: Dong Jin JEONG, Suwon-Si (KR); Min Young KIM, Suwon-Si (KR); Sin Gon KIM, Suwon-Si (KR); Kyung Seop LEE, Suwon-Si (KR)

(21) Appl. No.: 14/930,101

(22) Filed: Nov. 2, 2015

(30) Foreign Application Priority Data
Dec. 15, 2014 (KR) 10-2014-0180072

(51) Int. Cl. H01F 27/28; H05K 1/11

(52) U.S. Cl. CPC H01F 27/2804; H05K 1/111

(57) ABSTRACT

An electronic component includes a body including internal electrodes and a filler containing a metal component, a first insulating layer enclosing the internal electrodes, and a second insulating layer enclosing the first insulating layer.

### CROSS-REFERENCE TO RELATED APPLICATION

This application claims the benefit of priority to Korean Patent Application No. 10-2014-0180072, filed on Dec. 15, 2014 with the Korean Intellectual Property Office, the entirety of which is incorporated herein by reference.

### TECHNICAL FIELD

The present disclosure relates to an electronic component and a board having the same.

### BACKGROUND

An inductor, an electronic component, is a representative passive element configuring an electronic circuit together with a resistor and a capacitor to remove noise therefrom.

The electronic component may be mounted on a printed circuit board (PCB) by soldering to thereby be electrically connected to a circuit of the printed circuit board.

In accordance with miniaturization and high integration in this field, inductors need to be miniaturized and able to be operated under high-current, high-inductance conditions. To this end, a metal type inductor may have a filler containing a metal component in a region of the inductor enclosing a coil. Since insulation properties should be maintained between the coil and the filler containing the metal component in the above-mentioned inductor, an external surface of the coil is coated with an insulating material. However, in order to manufacture the above-mentioned inductor, high pressure may be applied to the filler containing the metal component at a low temperature in order to increase the density of the filler containing the metal component. In this process, the insulating material coated on the coil may be stripped or volatilized, resulting in a short circuit between the coil and the filler containing the metal component.

Korean Patent Publication No. 10-2014-0085997 discloses an inductor in which a filler containing a metal component is included in a body and an external surface of a coil is coated with an insulating layer, but does not mention the above-mentioned problem in which the insulating material coated on the coil is stripped or volatilized.

### SUMMARY

An aspect of the present disclosure provides an electronic component having improved insulating layers for coating internal electrodes to increase insulation reliability, thereby preventing leakage of a current from the internal electrodes to a body and being used under high inductance and high current conditions, and a board having the same.

According to an aspect of the present disclosure, an electronic component comprises a body including internal electrodes and a filler containing a metal component; a first insulating layer enclosing the internal electrodes; and a second insulating layer enclosing the first insulating layer.

A level of adhesion of the first insulating layer may be 3B or more according to the ASTM D3002/D3359 standard.

The first and second insulating layers may have a glass transition temperature (Tg) of 120° C. or more.

A sum of thicknesses of the first and second insulating layers may be 1 to 30 μm.

The first insulating layer may contain an epoxy resin, and the second insulating layer may contain a liquid crystalline polymer (LCP).

The electronic component may further comprise external electrodes disposed on end surfaces of the body in a length direction and connected to the internal electrodes.

The body may contain a thermosetting resin.

The internal electrodes maybe coils having a spiral shape.

According to another aspect of the present disclosure, a board having an electronic component may include: a printed circuit board including first and second electrode pads disposed thereon; and the electronic component mounted on the printed circuit board. The electronic component includes a body including internal electrodes and a filler containing a metal component, a first insulating layer enclosing the internal electrodes, and a second insulating layer enclosing the first insulating layer.

### BRIEF DESCRIPTION OF DRAWINGS

The above and other aspects, features and advantages of the present disclosure will be more clearly understood from the following detailed description taken in conjunction with the accompanying drawings.

FIG. 1 is a perspective view of an electronic component according to an exemplary embodiment in the present disclosure;

FIG. 2 is a cross-sectional view of the electronic component taken along line A-A′ of FIG. 1.

FIG. 3 is a partially enlarged view of part A of FIG. 2.

FIG. 4 is a perspective view of a board having an electronic component according to an exemplary embodiment in the present disclosure.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

### Electronic Component

Hereinafter, an electronic component according to an exemplary embodiment in the present disclosure, particularly, a thin film type inductor will be described. However, the electronic component is not necessarily limited thereto.

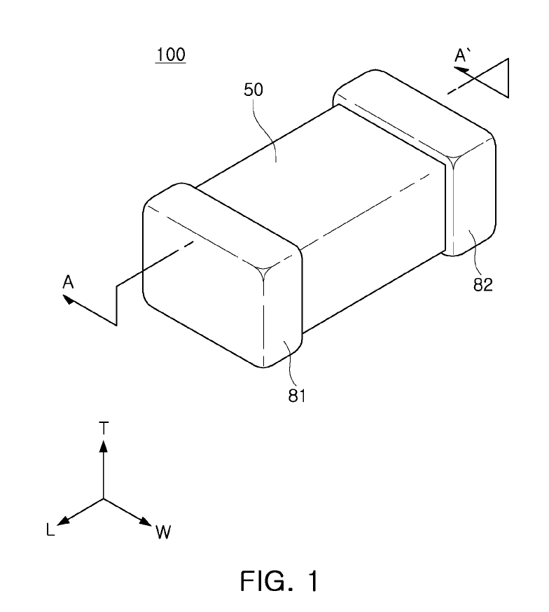

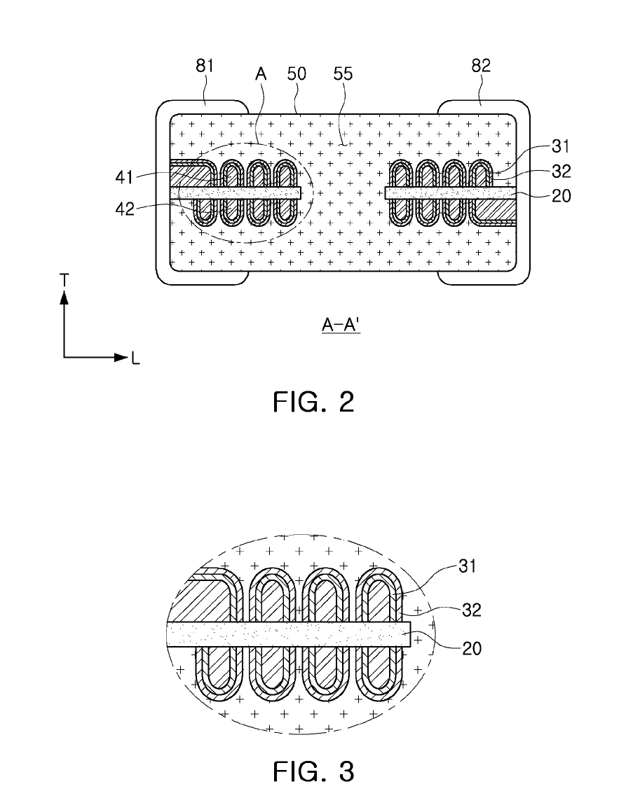

FIG. 1 is a perspective view of an electronic component according to an exemplary embodiment in the present disclosure. FIG. 2 is a cross-sectional view of the electronic component taken along line A-A′ of FIG. 1. FIG. 3 is a partially enlarged view of part A of FIG. 2.

Referring to FIGS. 1 and 2, an electronic component according to an exemplary embodiment in the present disclosure may include a body 50 including internal electrodes 41 and 42 and formed of a filler containing a metal component, a first insulating layer 31 enclosing the internal electrodes 41 and 42, and a second insulating layer 32 enclosing the first insulating layer 31.

Generally, an electronic component such as an inductor needs to be operated under high-current and high-inductance conditions. To this end, there may be a case in which the filler in the electronic component contains the metal component. Since insulation properties between the internal electrodes of the electronic component and the filler need to be maintained in the electronic component, external surfaces of the internal electrodes may be coated with an insulating material. However, when high temperature or high pressure is required in a process of manufacturing the electronic component, a problem in which the insulating material coated on the internal electrodes is stripped or volatilized may occur. In this case, the internal electrodes and the filler are not insulated from each other, such that short circuits may be generated between the internal electrodes and the filler.

In the electronic component 100 according to an exemplary embodiment in the present disclosure, the insulating material coating the internal electrodes 41 and 42 may be formed of the first and second insulating layers 31 and 32, and the first insulating layer 31 may contain a material having excellent adhesive force to adhere to the internal electrodes 41 and 42, and the second insulating layer 32 may contain a material having good insulation properties with respect to the filler.

Hereinafter, respective components of the electronic component 100 according to an exemplary embodiment in the present disclosure will be described.

The body 50 may form the exterior of the electronic component 100 and may be formed of any material exhibiting magnetic properties. For example, the body 50 may be formed by filling ferrite or a metal magnetic powder. As described above, when the body 50 contains the magnetic metal powder, insulation properties between the internal electrodes and the magnetic metal powder may be problematic.

The ferrite may be, for example, Mn—Zn-based ferrite, Ni—Zn-based ferrite, Ni—Zn—Cu-based ferrite, Mn—Mg-based ferrite, Ba-based ferrite, Li-based ferrite, or the like.

The magnetic metal powder may contain one or more selected from the group consisting of Fe, Si, Cr, Al, and Ni. For example, the magnetic metal powder may be a Fe—Si—B—Cr-based amorphous metal, but is not necessarily limited thereto.

The magnetic metal powder may have a particle size of 0.1 to 90 μm and may be contained in a thermosetting resin such as an epoxy resin, polyimide, or the like, to be dispersed in the thermosetting resin.

The internal electrodes 41 and 42 disposed in the body 50 may be coils having a spiral shape.

A first internal electrode 41 having a coil shape may be formed on a first surface of a substrate 20 disposed in the body 50, and a second internal electrode 42 having a coil shape may be formed on a second surface of the substrate 20 opposing the first surface of the substrate 20. The first and second internal electrodes 41 and 42 may be electrically connected to each other by a via (not illustrated) formed in the substrate 20.

The first and second internal electrodes 41 and 42 may be formed by performing electroplating.

The internal electrodes 41 and 42 and the via (not illustrated) may be formed of a metal having excellent electrical conductivity, for example, silver (Ag), palladium (Pd), aluminum (Al), nickel (Ni), titanium (Ti), gold (Au), copper (Cu), platinum (Pt), or alloys thereof.

The internal electrodes 41 and 42 may be coated with the first insulating layer 31, and the first insulating layer 31 may be re-coated with the second insulating layer 32, such that an insulating layer having a two-layer structure may be formed.

The first and second insulating layers 31 and 32 may be formed by a method well-known in the art such as a screen printing method, a photo-resist (PR) exposure and development method, a spray application method, or the like.

The first insulating layer 31 may be formed of a material enhancing the adhesive strength of the internal electrodes 41 and 42. Therefore, even when the body 50 is hardened under high-temperature and high-pressure conditions in order to manufacture the electronic component 100, the first insulating layer 31 may not be stripped or volatilized and lost.

In detail, a level of adhesion of the first insulating layer 31 measured in a cross-cut test, according to the ASTM D3002/D3359 standard, needs to be 3 B or more. The level of adhesion of the first insulating layer 31 was measured by performing a cross-hatch adhesion test, according to the ASTM D3002/D3359 standard. Eleven lines were drawn at intervals of 1 mm in each of vertical and horizontal directions on a sample using a knife to form a lattice having hundred squares having sides of 1 mm. Then, adhesive tape was attached to a cut surface of the sample, and a state of a stripped surface was measured and evaluated while removing the adhesive tape. When the stripped surface was not present, the case was evaluated as 5 B. When an area of the stripped surface was less than 5% of a total area, the case was evaluated as 4 B. When the area of the stripped surface was 5% to 15% of the total area, the case was evaluated as 3 B. When the area of the stripped surface was 15% to 35% of the total area, the case was evaluated as 2 B. When the area of the stripped surface was 35% to 65% of the total area, the case was evaluated as 1 B. When the area of the stripped surface exceeded 65% of the total area, the case was evaluated as 0 B.

When the level of adhesion of the first insulating layer 31 is lower than 3 B, the adhesion is not sufficient, such that the first insulating layer 31 may be stripped from the internal electrodes 41 and 42 at high temperature and under high pressure. Therefore, the level of adhesion of the first insulating layer 31 may be 3B or more. As the adhesion of the first insulating layer 31 to the internal electrodes 41 and 42 is increased, it maybe advantageous in preventing a stripping phenomenon generated at high temperature and under high pressure. Therefore, an upper limit of the adhesion may not be determined.

A glass transition temperature (Tg) of the first insulating layer 31 may be 120° C. or more. When the glass transition temperature of the first insulating layer 31 is lower than 120° C., the first insulating layer 31 may be volatilized and lost or hardness of the first insulating layer 31 maybe decreased when the body 50 is hardened under high-temperature and high-pressure conditions. As such, the level of adhesion between the first insulating layer 31 and the internal electrodes 41 and 42 may be decreased.

The second insulating layer 32 may contain a material having excellent insulation properties with respect to the filler in the body 50. In addition, a glass transition temperature (Tg) of the second insulating layer 32 may be 120° C. or more, similar to that of the first insulating layer 31. When the glass transition temperature of the second insulating layer 32 is lower than 120° C., the second insulating layer 32 may be volatilized and deformed when the body 50 is hardened under high-temperature and high-pressure conditions, such that impurities may permeate from the filler into the second insulating layer 32, thereby decreasing insulation capability.

The first and second insulating layers 31 and 32 may satisfy the above-mentioned conditions. To this end, the first and second insulating layers 31 and 32 may contain one or more selected from the group consisting of epoxy, polyimide, acryl, Teflon, and a liquid crystalline polymer (LCP).

In particular, the first insulating layer 31 may contain an epoxy resin having excellent adhesion, and the second insulating layer 32 may contain a liquid crystalline polymer having excellent insulation properties to effectively insulate the internal electrodes 41 and 42 and the filler from each other.

A sum of thicknesses of the first and second insulating layers 31 and 32 maybe 1 to 30 μm. When the sum of the thicknesses of the first and second insulating layers 31 and 32 is less than 1 μm, the first and second insulating layers 31 and 32 may be relatively thin, such that insulation properties of the first and second insulating layers 31 and 32 may not be secured, and the first and second insulating layers 31 and 32 may be easily stripped at high temperature and high pressure. When the sum of the thicknesses of the first and second insulating layers 31 and 32 exceeds 30 μm, inductance of the electronic component 100 may be decreased, and a size of the electronic component 100 may be increased. The sum of the thicknesses of the first and second insulating layers 31 and 32 may be 1 to 30 μm.

The substrate 20 may be, for example, a polypropylene glycol (PPG) substrate, a ferrite substrate, a metal-based soft magnetic substrate, or the like. The substrate 20 may have a through-hole formed in a central portion thereof to penetrate therethrough, wherein the through-hole may be filled with a magnetic material to form a core part 55. The core part 55 filled with the magnetic material may be formed, thereby improving inductance (Ls).

One end portion of the first internal electrode 41 formed on the first surface of the substrate 20 may be exposed to an end surface of the body 50 in a length L direction, and one end portion of the second internal electrode 42 formed on the second surface of the substrate 20 may be exposed to the opposite end surface of the body 50 in the length L direction.

The internal electrodes 41 and 42 exposed to both end surfaces of the body 50 in the length L direction may be electrically connected to first and second external electrodes 81 and 82, respectively.

The first and second external electrodes 81 and 82 may be formed of a metal having excellent electrical conductivity, for example, nickel (Ni), copper (Cu), tin (Sn), silver (Ag), or the like, or alloys thereof.

Table 1 illustrates the occurrence of defects depending on the number of insulating layers and thicknesses of the insulating layers.

Table 1 illustrates levels of inductance of inductors (Inventive Examples) including first and second insulating layers according to an exemplary embodiment in the present disclosure and inductors (Comparative Examples) including a single insulating layer or first and second insulating layers according to the related art, measured after the inductors were hardened at high pressure and a temperature of 230° C.

In Table 1, for Inventive and Comparative Examples including two insulating layers, a first insulating layer was formed of an epoxy resin having a level of adhesion based on the ASTM D3002/D3359 standard of 3 B or more and a glass transition temperature of 120° C. or more, and a second insulating layer was formed of a liquid crystalline polymer having a glass transition temperature of 120° C. or more. In Table 1, for Comparative Examples including a single insulating layer, an insulating layer was formed of an epoxy resin having a level of adhesion, based on the ASTM D3002/D3359 standard, of 3 B or more and a glass transition temperature of 120° C. or more.

Levels of inductance of one hundred samples were measured according to respective conditions to show defect rates. It can be appreciated that, when levels of inductance of all samples were not found defective, insulation properties between internal electrodes and a filler were secured, such that an insulating layer was excellent. When levels of inductance of some samples were found defective, insulation properties between internal electrodes and a filler were not secured, such that adhesion or insulating properties of the insulating layer were problematic.

TABLE 1

| | | | Number of | |
|---|---|---|---|---|
| | | Sum (μm) of | Defective | Adhesion |
| | Number of | Thicknesses of | Samples in | and |
| | Insulating | Insulating | terms of | Insulation |
| | Layers | Layers | Inductance | Properties |
| Comparative | 1 | 0.5 | 5 | Defective |
| Example 1 | | | | |
| Comparative | 1 | 1 | 3 | Defective |
| Example 2 | | | | |
| Comparative | 1 | 10 | 2 | Defective |
| Example 3 | | | | |
| Comparative | 1 | 30 | 2 | Defective |
| Example 4 | | | | |
| Comparative | 2 | 0.5 | 3 | Defective |
| Example 5 | | | | |
| Inventive | 2 | 1 | 0 | Excellent |
| Example 1 | | | | |
| Inventive | 2 | 10 | 0 | Excellent |
| Example 2 | | | | |
| Inventive | 2 | 30 | 0 | Excellent |
| Example 3 | | | | |

Table 1 shows that, in Comparative Examples 1 to 4 in which an insulating layer was formed as a single layer using an epoxy resin, defective samples regarding inductance were present, and adhesion and insulation properties were problematic.

It can be seen that in Comparative Example 5, in which the sum of thicknesses of insulating layers was less than 1 μm, even though the insulating layers were formed in a two-layer structure, defective samples regarding inductance were present, and adhesion and insulation properties were problematic.

In Inventive Examples 1 to 3 in which insulating layers were formed in a two-layer structure and the sum of thicknesses of the insulating layers was 1 μm or more, defective samples regarding inductance were unexpectedly not present, and adhesion and insulation properties were unexpectedly excellent.

Table 2 illustrates the occurrence of defects depending on the adhesion of the first insulating layer 31 and glass transition temperatures of the first and second insulating layers 31 and 32.

Table 2 illustrates levels of inductance of inductors. The Inventive Examples include a first insulating layer having a level of adhesion, based on the ASTM D3002/D3359 standard, of 3 B or more and a glass transition temperature of 120° C. or more, and a second insulating layer having a glass transition temperature of 120° C. or more. The Comparative Examples include first and second insulating layers formed so that any one of the above-mentioned conditions was not satisfied. The Inventive and Comparative Examples were measured after the inductors were hardened under high pressure and a temperature of 230° C. The first insulating layer was formed of an epoxy resin, and the second insulating layer was formed of a liquid crystalline polymer.

As in Table 1, levels of inductance of one hundred samples were measured according to respective conditions to show defect rates. When levels of inductance of all samples were not found defective, insulation properties between internal electrodes and a filler were secured, such that an insulating layer was unexpectedly excellent. When levels of inductance of some samples were found defective, insulation properties between internal electrodes and a filler were not secured, such that adhesion or the insulation properties of the insulating layer were unexpectedly problematic.

TABLE 2

| | Adhesion | Glass Transition | Number of | |
|---|---|---|---|---|
| | (B) | Temperatures | Defective | Adhesion |
| | of First | (° C.) of First | Samples in | and |
| | Insulating | and Second | terms of | Insulation |
| | Layer | Insulating Layers | Inductance | Properties |
| Comparative | 1 | 100 | 4 | Defective |
| Example 1 | | | | |
| Comparative | 3 | 100 | 2 | Defective |
| Example 2 | | | | |
| Comparative | 4 | 100 | 1 | Defective |
| Example 3 | | | | |
| Comparative | 1 | 120 | 2 | Defective |
| Example 4 | | | | |
| Inventive | 3 | 120 | 0 | Excellent |
| Example 1 | | | | |
| Inventive | 4 | 120 | 0 | Excellent |
| Example 2 | | | | |
| Comparative | 1 | 140 | 3 | Defective |
| Example 5 | | | | |
| Inventive | 3 | 140 | 0 | Excellent |
| Example 3 | | | | |
| Inventive | 4 | 140 | 0 | Excellent |
| Example 4 | | | | |

Table 2 illustrates that, in Comparative Examples 1, 4, and 5 in which adhesion of the first insulating layer was less than 3 B, defective samples regarding inductance were present, regardless of glass transition temperatures, and adhesion and insulation properties were problematic.

In Comparative Examples 1 to 3 in which glass transition temperatures were less than 120° C., defective samples regarding inductance were present, regardless of adhesion of the first insulating layer, and adhesion and insulation properties were problematic.

In Inventive Examples 1 to 4 in which levels of adhesion of the first insulating layer were 3 B or more and glass transition temperatures were 120° C. or more, defective samples regarding inductance were not observed, and adhesion and insulation properties were unexpectedly excellent.

### Board Having Electronic Component

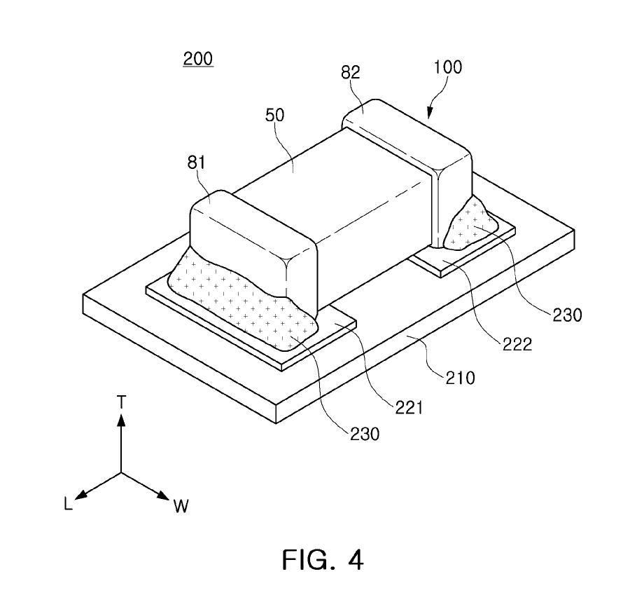

FIG. 4 is a perspective view of a board having an electronic component according to an exemplary embodiment in the present disclosure.

Referring to FIG. 4, a board 200 having an electronic component according to an exemplary embodiment in the present disclosure may include a printed circuit board 210 including first and second electrode pads 221 and 222 disposed thereon and the electronic component 100 mounted on the printed circuit board 210. The electronic component may include the body 50 including the internal electrodes 41 and 42 and filled with the filler containing the metal component, the first insulating layer 31 enclosing the internal electrodes 41 and 42, and the second insulating layer 32 enclosing the first insulating layer 31.

The electronic component 100 may be soldered to the printed circuit board 210 by solders 230 to thereby be electrically connected to the printed circuit board 210, in a state in which the first and second external electrodes 81 and 82 formed on both end surfaces thereof are positioned on the first and second electrode pads 221 and 222, respectively, to contact the first and second electrode pads 221 and 222, respectively.

The electronic component 100 may be the same as the electronic component 100 described above. Therefore, descriptions of features the same as those of the electronic component 100 according to the exemplary embodiment in the present disclosure described above except for the above-mentioned description will be omitted.

As set forth above, according to exemplary embodiments in the present disclosure, an electronic component has improved insulating layers for coating internal electrodes to increase insulation reliability, thereby preventing leakage of a current from the internal electrodes to a body and being used under high inductance and high current conditions.

While exemplary embodiments have been shown and described above, it will be apparent to those skilled in the art that modifications and variations could be made without departing from the scope of the present invention as defined by the appended claims.

What is claimed is:

1. An electronic component comprising:
a body including internal electrodes and a filler containing a metal component;
a first insulating layer enclosing the internal electrodes; and
a second insulating layer enclosing the first insulating layer.

2. The electronic component of claim 1, wherein a level of adhesion of the first insulating layer is 3 B or more according to the ASTM D3002/D3359 standard.

3. The electronic component of claim 1, wherein the first and second insulating layers have a glass transition temperature (Tg) of 120° C. or more.

4. The electronic component of claim 1, wherein a sum of thicknesses of the first and second insulating layers is 1 to 30 μm.

5. The electronic component of claim 1, wherein the first insulating layer contains an epoxy resin, and
the second insulating layer contains a liquid crystalline polymer (LCP).

6. The electronic component of claim 1, further comprising external electrodes disposed on end surfaces of the body in a length direction and connected to the internal electrodes.

7. The electronic component of claim 1, wherein the body contains a thermosetting resin.

8. The electronic component of claim 1, wherein the internal electrodes are coils having a spiral shape.

9. A board having an electronic component, comprising:
a printed circuit board including first and second electrode pads disposed thereon; and
the electronic component mounted on the printed circuit board,
wherein the electronic component includes :
a body including internal electrodes and a filler containing a metal component;
a first insulating layer enclosing the internal electrodes; and
a second insulating layer enclosing the first insulating layer.

10. The board of claim 9, wherein a level of adhesion of the first insulating layer is 3 B or more according to the ASTM D3002/D3359 standard.

11. The board of claim 9, wherein the first and second insulating layers have a glass transition temperature (Tg) of 120° C. or more.

12. The board of claim 9, wherein a sum of thicknesses of the first and second insulating layers is 1 to 30 μm.
